(19) United States
(12) Patent Application Publication
(10) Pub. No.: US 2018/0235092 A1
(43) Pub. Date: Aug. 16, 2018

(54) HOUSING WITH FLUID DUCT

(71) Applicant: Robert Bosch GmbH, Stuttgart (DE)

(72) Inventors: Michael Schermann, Appenweier (DE); Asli Arslan-Huerst, Karlsruhe (DE); Dirk Vollmer, Achern (DE); Linh-Thao Stubenbord, Buehl (DE); Ralf Lehmann, Oberkirch (DE); Wolfgang Glueck, Baden-Baden (DE)

(21) Appl. No.: 15/749,947

(22) PCT Filed: Jun. 16, 2016
(86) PCT No.: PCT/EP2016/063901

§ 371 Date: Feb. 2, 2018

(30) Foreign Application Priority Data
Aug. 7, 2015 (DE) 10 2015 215 102.6

(51) Int. Cl. H05K 5/02; H05K 5/00; F04D 25/06

(52) U.S. Cl. CPC H05K 5/0213; F04D 25/068; H05K 5/0217; H05K 5/0017

(57) ABSTRACT

The invention relates to a housing (1), in particular for a control unit of a fan motor, having at least two housing elements (10, 30) and having a connecting element (50), wherein the housing elements (10, 30) interact with the connecting element (50), and wherein the brought-together housing elements (10, 30) form an interior region (5). According to the invention, a duct (40) is formed which, before and/or during the assembly of the housing (1), in particular before and/or during the bringing-together of the housing elements (10, 30), connects the interior region (5) and the surroundings of the housing (1) and permits a fluid flow between the interior region (5) and the surroundings, and which, upon the completion of the assembly process, is closed off by way of the interaction of at least one housing element (10, 30) and the connecting element (50).

### BACKGROUND OF THE INVENTION

The invention relates to a housing in particular for a control unit of a fan motor, with at least two housing elements and a connecting element, wherein the housing elements interact with the connecting element, and wherein the brought-together housing elements form an inner region.

Housings consisting of two housing elements and a sealing element are already known. The sealing element is arranged between the two housing elements. The housings have an inner region in which it is possible in particular for electrical components to be arranged. The two housing elements are brought together during the assembly. Here, air is displaced out of the inner region of the housing. The displaced air flows out of the inner region past the sealing element into the surroundings. The air flowing past can lead to undesirable displacement of the sealing means. The displacement of the sealing means can result in the housing being unsealed in the region of the displaced sealing means. In order to counteract undesirable displacement, additional openings are provided in the housing elements. However, the additional openings have to be closed off again in an additional, subsequent working step. Also, the openings must exist at the moment when the housing elements are brought together. An assembly sequence is correspondingly fixedly predefined.

### SUMMARY OF THE INVENTION

The housing according to the invention has the advantage that the assembly and production of the housing is simplified in comparison with known housings such that the assembly sequence can be varied in a more flexible manner. In particular, the sequence is independent of the presence of openings which allow fluid flow out of the inner region of the housing. Also, the sealing of the housing is improved since the connecting element is not displaced in an unwanted manner during the assembly and, furthermore, no additional openings have to be formed on the housing elements. Also, the openings do not need to be closed off again by way of an additional, subsequent working step.

It is regarded as being advantageous for the channel to be closed off by the connecting element upon completion of the assembly. The closure of the channel by means of the connecting element brings about prevention of fluid flow through the channel after completion of the assembly, or after completion of the bringing-together of the housing elements. Consequently, no liquids are able to enter into the housing via the channel and, in particular, damage the control electronics arranged in the inner region. For example, the housing is used as an electronics housing, in particular as control electronics for a fan, in a vehicle. Particular requirements for the housing, in particular concerning leak-tightness and stability, apply in this case.

It is furthermore advantageous for the connecting element to connect the housing elements in a sealed manner upon completion of the assembly of the housing. The connecting element thus prevents the development of fluid flow between the housing elements. A corresponding formation results in particular in entry of fluids into the housing, in the region of the interaction of the housing elements and the connecting element, being prevented.

It is advantageous for the at least one channel to be formed by way of a recess or at least one aperture in one of the housing elements. A recess or a narrowing or an aperture is an easily producible and thus a cost-effective solution for the formation of a channel. In particular, the recess or the narrowing or an aperture may already be formed during the production, in particular during the casting or deep-drawing of the housing elements.

It is particularly advantageous for the housing elements to interact by means of a tongue-and-groove connection. The second housing element has a tongue. The first housing element has a corresponding groove. Furthermore, the tongue engages into the groove. A tongue-and-groove connection prevents in particular displacement of the housing elements relative to one another. It is also advantageous that a tongue-and-groove connection is easily producible. A tongue-and-groove connection of the housing elements has a positive effect on the stability of the housing. Moreover, the housing elements can be easily assembled by way of a tongue-and-groove connection.

It is advantageous for the groove of the first housing element and the tongue of the second housing element to be formed so as to at least partially, in particular completely, extend circumferentially around the housing elements. The at least partially circumferential formation of the tongue-and-groove connection results in, inter alia, the improvement of the stability of the housing, in particular against displacement of the housing elements relative to one another.

It is advantageous for the channel to be formed by way of a recess, a narrowing or an aperture in the tongue of the second housing element. It is also advantageous, in particular, for the recess to be formed as a notch, preferably having a triangular, a square or a semicircular form, or as a slot. A recess, a narrowing or an aperture is easily producible and does not influence the assembly of the housing.

It is furthermore advantageous for the groove to at least partially guide the connecting element, in particular for the connecting element to extend inside the groove. The guidance of the connecting element through the groove allows easy assembly. Also, it is possible for the connecting element to be already arranged inside the groove at an earlier working step.

It is particularly advantageous for the groove to have a partial protuberance, wherein, as a result of the partial protuberance, the connecting element forms a channel prior to and/or during the assembly, in particular the channel is formed in the region of the partial protuberance. Preferably, it is possible for any desired number of partial protuberances to be provided.

It is particularly advantageous for the connecting element to be formed as a wet seal. The wet seal improves the sealing of the housing. In particular, the wet seal is displaced by the housing elements during the assembly, whereby uniform distribution of the wet seal is ensured. The uniform distribution leads in turn to uniform sealing of the housing.

It is particularly advantageous for the connecting element to be of cylindrical form. The production and fitting of a cylindrical connecting element is easy and thus inexpensive. The cylindrical connecting element can be produced in an easy and cost-effective manner.

It is particularly advantageous for the connecting element to have a partially reduced cross section, in particular a narrowing, preferably to have a recess, wherein the partially reduced cross section results in the channel being formed during the assembly. The formation of a partially reduced cross section in the connecting element can be realized very easily and is thus cost-effective.

It is particularly advantageous for two sealing elements to be formed, wherein the channel is formed between the two connecting elements prior to and during the assembly. The connecting elements make contact with one another, and close off the channel, upon completion of the assembly. A corresponding construction can be realized in an easy and cost-effective manner.

It is advantageous for two or more channels to be formed prior to and/or during the assembly of the housing, in particular prior to and/or during the bringing-together of the housing elements, wherein the channels are closed off upon completion of the assembly. The formation of multiple channels leads to improved, in particular more uniform, outward flow of the air out of the inner region of the housing. In particular, the quantity of air which is displaced inside the housing elements is distributed between multiple channels.

It is advantageous for one of the housing elements to have a cooling structure with an elevated surface, in particular cooling fins.

### BRIEF DESCRIPTION OF THE DRAWINGS

Exemplary embodiments are illustrated in the figures and discussed in more detail in the description below. In the drawings:

FIG. 1 shows a plan view of a housing,

FIG. 2 shows a first housing element, a second housing element and a connecting element in a sectional illustration,

FIGS. 3a to 3c show the individual stages for the assembly of the housing,

FIG. 4 shows the housing with electrical lines,

FIG. 5 shows a connecting element which, due to the pressure increase and the fluid flow, out of the housing, associated with said pressure increase, was not able to be properly displaced by the tongue,

FIG. 6 shows an exemplary embodiment for the formation of a housing according to the invention with a second housing element which has a tongue in which there is formed a recess which forms a channel,

FIGS. 7a to 7c show the individual stages for the assembly of the housing with a recess which forms a channel,

FIG. 8 shows a further embodiment with a connecting element which has a recess at one point,

FIG. 9 shows a further embodiment, wherein the groove has a partial protuberance,

FIGS. 10, 11 and 12 show a further embodiment with two connecting elements arranged partly parallel to one another, and

FIG. 13 shows a further embodiment with a bore.

### DETAILED DESCRIPTION

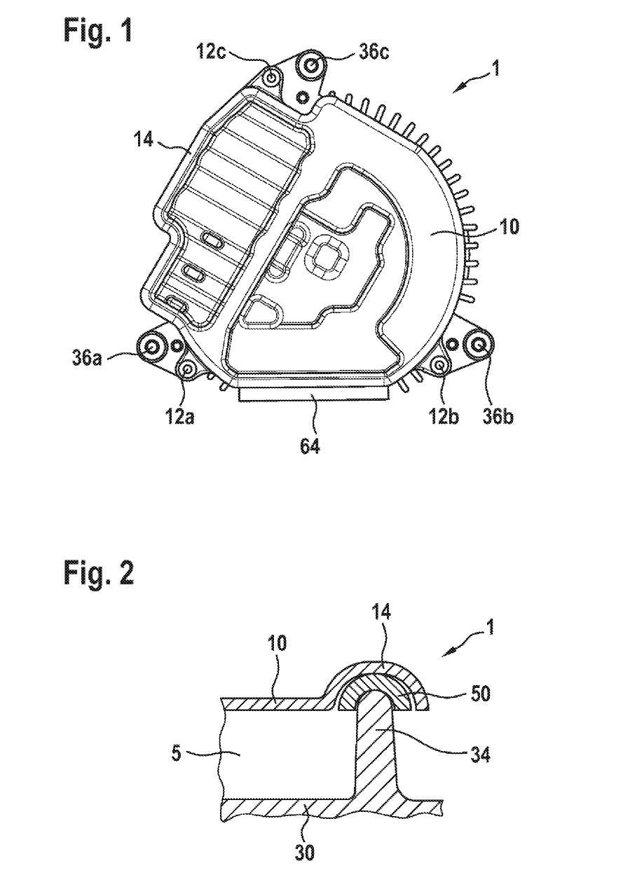

A plan view of a housing 1 is illustrated in FIG. 1. The housing 1 comprises a first housing element 10 and a second housing element 30. The first housing element 10 is preferably formed as a deep-drawn part. The formation as a deep-drawn part allows easy and low-cost production of the first housing element 10. The second housing element 30 is preferably produced by means of a pressure die-casting technique, in particular as an aluminum pressure die casting or magnesium pressure die casting. In particular, the housing 1 is formed so as to accommodate electrical components, preferably an electrical circuit board. The electrical circuit board may form in particular the control unit of an electrical drive. Preferably, the circuit board forms an electrical control unit for a fan motor, in particular the fan motor of an HVAC system, or a pump. The second housing element 30 has cooling bodies whose main function is the heat dissipation of heat generated during the operation of the electrical components. The second housing element 30 is substantially concealed by the first housing element 10 in FIG. 1. The first housing element 10 has screwing-in points 12a, 12b, 12c. The second housing element 30 has screwing-in points 32a, 32b, 32c which are concealed by the screwing-in points 12a, 12b, 12c of the first housing element 10 in FIG. 1. The two housing elements 10, 30 are connected to one another by screws by means of the screwing-in points 12a, 12b, 12c and 32a, 32b, 32c.

A plug-in contact may be attached to the housing via an opening 64.

The second housing element 30 has fastening regions, in particular three fastening regions 36a, 36b, 36c. The fastening regions 36a, 36b, 36c serve for the attachment of the housing 1 to a component of the vehicle, in particular for the attachment to a frame.

The first housing element 10 also has a groove 14 which extends circumferentially around the edge of the housing element 10. The groove 14 serves for accommodating a connecting means 50. The connecting means 50 may be formed in particular as a sealing means, preferably as a wet seal and/or adhesive, wherein the connecting means 50 connects the two housing elements 10, 30 to one another. The connecting means 50 is intended to prevent the entry of fluids into the housing 1.

In particular, the connecting means 50 may, in addition to its sealing function, connect the two housing elements 10, 30 fixedly to one another. In this case, the connecting means 50 is formed in particular as an adhesive. The connecting means 50 adhesively bonds the two housing elements 10, 30 to one another.

FIG. 2 shows the first housing element 10 and the second housing element 30 in a sectional illustration. The first housing element 10 forms a cover for the second housing element 30. The first housing element 10 has a groove 14. The connecting means 50 is arranged inside the groove 14. The second housing element 30 has a circumferential tongue 34 which extends in the longitudinal direction. When the housing 1 has been assembled, the edge of the tongue 34 is arranged inside the groove 14, in particular the edge engages into the groove 14. A connecting means 50 is at least partially, in particular completely, arranged between the first housing element 10 and the second housing element 30. The two housing elements 10, 30 are connected fixedly to one another by way of a threaded connection and the screwing-in points 12, 32 during the assembly. The connecting means 50 is compressed during the assembly. The connecting means 50 establishes an adhesive, fluid-tight connection between the first housing element 10 and the second housing element 30.

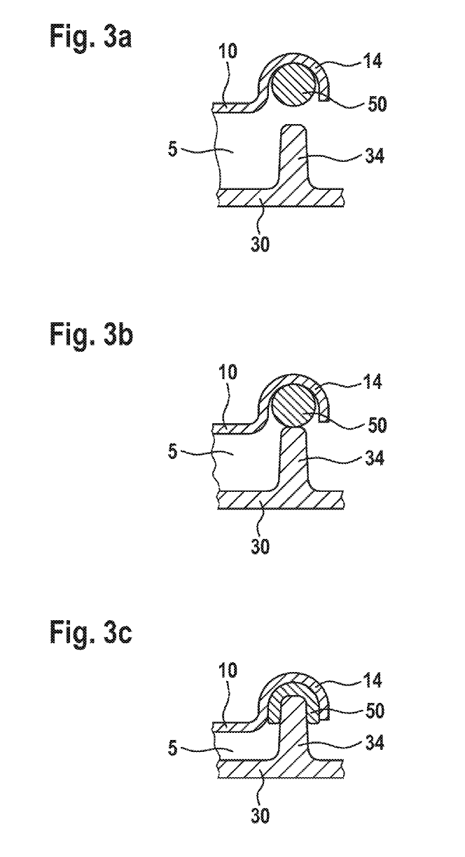

The individual stages for the assembly of the housing 1 are illustrated in FIGS. 3a to 3c. The first housing element 10 is connected to the second housing element 30 during the assembly.

FIG. 3a shows the initial state. Here, the connecting element 50 is arranged inside the groove 14 of the first housing element 10. The connecting element 50 has a circular cross section.

In FIG. 3b, the housing elements 10, 30 have been moved toward one another. The bringing-together of the housing elements 10, 30 has partially taken place. Fluid flow out of the inner region 5 into the surroundings is possible only to a limited extent, in particular the connecting element 50 prevents fluid flow between the housing elements 10, 30. The connecting element 50 makes contact with the tongue 34 of the second housing element 30. If the housing 1 has no openings, then a positive pressure forms during the further bringing-together of the housing elements 10, 30.

FIG. 3c illustrates the housing 1 after completion of the assembly of the housing 1. However, the completion of the assembly cannot be equated with the full completion of a saleable product. Rather, the housing elements 10, 30 were connected to one another upon completion of the assembly of the housing 1. A housing 1 with an inner region 5 was thus produced. The first housing element 10 and the second housing element 30 are in the final state. As far as the assembly is concerned, the two housing elements 10, 30 have been brought together or joined or assembled completely. The connecting element 50 has been displaced by the tongue 34 of the second housing element 30 and has in particular a C-shaped cross section. In order to achieve the best possible connection and/or sealing by the connecting element 50, the latter has to be displaced in a uniform manner. In particular, a connecting element 50 displaced uniformly is illustrated in FIG. 3c. Here, “displacement” may be understood in particular to also mean a uniform arrangement, in particular deformation, of the connecting element 50 during the assembly of the housing 1. In order to achieve an optimal arrangement or optimal displacement of the connecting element 50, outward flow of the fluid out of the inner region 5 of the housing 1 has to be made possible during the assembly. Such outward flow of the fluid, in particular through openings at the electrical outputs or inputs into the housing 1 or out of the housing 1, is known from the prior art. However, said openings may be closed off or not formed at all, depending on the assembly sequence and the design of the housing 1. If the air is unable to flow away out of the inner region 5, then a positive pressure forms inside the housing 1 as a result of the bringing-together of the housing elements 10, 30. The formation of such a positive pressure can occur in housings which do not conform to the invention, in particular if the assembly sequence thereof has been changed.

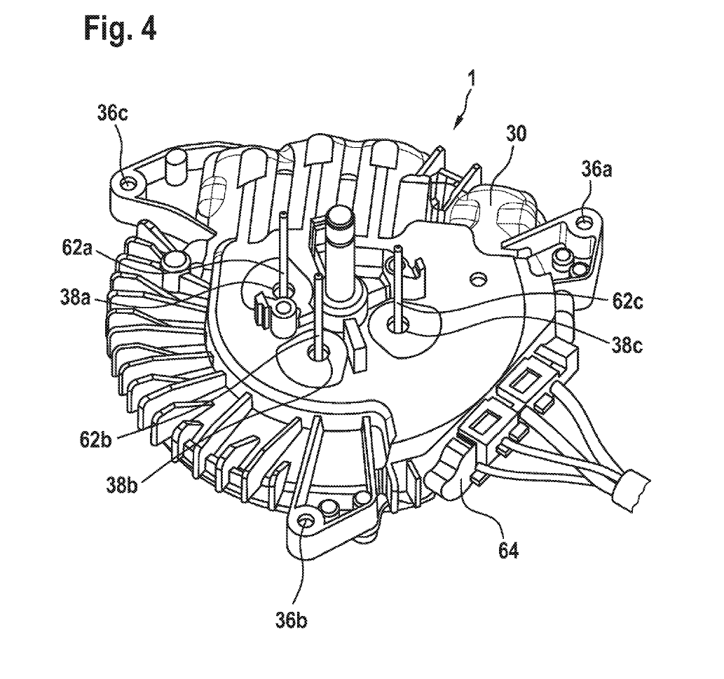

In FIG. 4, an exemplary housing 1 is illustrated. Compared with the illustration in FIG. 1, the housing 1 in FIG. 4 has been rotated. The second housing element 30 conceals the first housing element 10. The second housing element 30 has openings 38a, 38b and 38c for the connection of the electrical drive. The openings 38a, 38b and 38c are formed in particular as holes. Electrical lines 62a, 62b, 62c, which establish a connection, in particular an electrical connection, between the electrical drive, in particular a stator, and the control unit 60, extend through the recess 38a, 38b and 38c. The connecting plug 64 is also illustrated in FIG. 4. The connecting plug 64 allows an electrical connection between the control unit 60 and further components of the vehicle, in particular a communication connection or an energy supply connection.

The fluid, in particular air, is forced out of the inner region 5, that is to say the region between the first housing element 10 and the second housing element 30, during the assembly of the housing 1. Here, the fluid escapes in particular via the openings 38a, 38b and 38c or via the openings for the connecting plug 64, the latter not yet being connected to the housing 1.

If the openings 38 and/or the opening for the connecting plug 64 are already closed off in an air-tight manner due to a changed assembly sequence, then a pressure increase inside the housing 1 can occur when the first housing element 10 and the second housing element 30 are brought together. A pressure increase can also occur if no additional openings are provided. Said pressure increase prevents the optimum displacement of the connecting element 50. The fluid flows past the connecting element 50 and consequently prevents an optimum arrangement, in particular deformation, preferably formation, of the connecting element 50. In particular, unwanted channels 100 form, these making it possible for fluid to flow into the housing 1 at a later point in time.

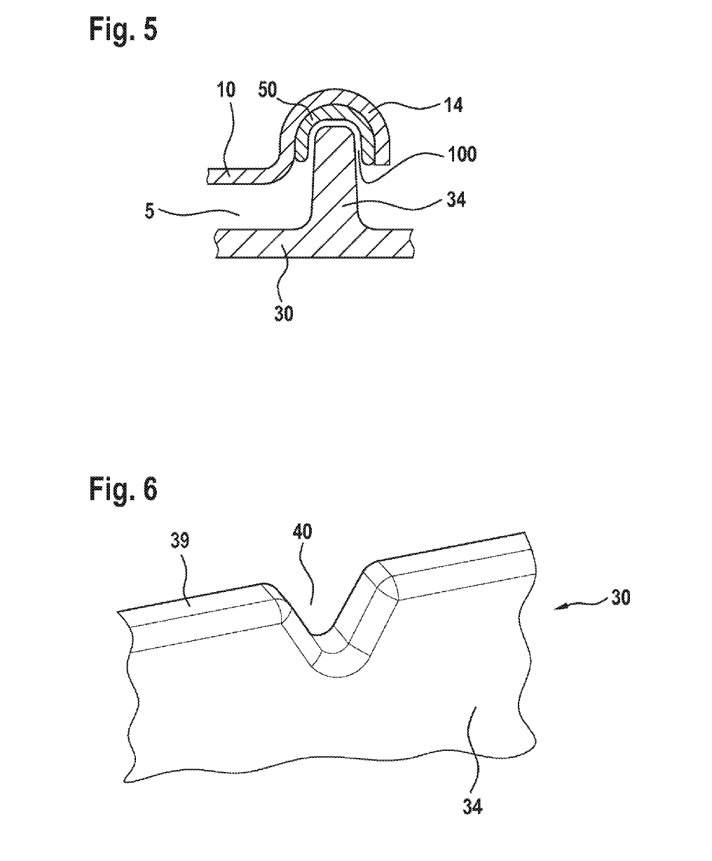

FIG. 5 illustrates a connecting element 50 which, due to the pressure increase and the fluid flow, out of the housing 1, associated with said pressure increase, was not able to be properly displaced by the tongue 34. In particular, the connecting element 50 can be blown out by the outwardly flowing fluid flow, and defects in the connecting element 50 can arise. An unwanted channel 100 formed during the assembly and makes it possible for liquids to enter into the housing 1. The positive pressure was released by way of the unwanted channel 100. Such unwanted channels can arise during the assembly of housings known in the prior art.

According to the invention, the positive pressure generated, or the fluid flow out of the inner region 5, is made possible by a corresponding formation of the first housing element 10, the second housing element 30 and/or the connecting element 50. The positive pressure is generated by the minimization of the volume of the inner region 5 resulting from the bringing-together of the housing elements 10, 30 during the assembly of the housing 1. During the assembly of known housings, the positive pressure is in particular able to be released only such that the connecting element 50 is partially displaced at one or multiple points and an unwanted channel 100 forms.

According to the invention, a channel 40 is formed, which connects the inner region 5 and the surroundings of the housing 1, and permits fluid flow, prior to and/or during the assembly of the housing 1, in particular prior to and/or during the bringing-together of the housing elements 10, 30.

FIG. 6 illustrates an exemplary embodiment for the formation of a housing 1 according to the invention with a second housing element 30 which has a tongue 34 in which there is formed a recess which forms a channel. The tongue 34 of the second housing element 30 has at at least one point a recess, in particular an edge region of the tongue 34, which region is sunken in a punctiform manner, preferably a narrowing or a notch. The notch is of substantially triangular form. Furthermore, the recess is situated in the edge region of the tongue 34. The recess is formed in that region of the tongue 34 which faces toward the groove 14.

According to a refinement of the invention, it is possible for the channel 40 to be formed by way of a semicircular, a triangular or a square recess or narrowing in one of the housing elements 10, 30.

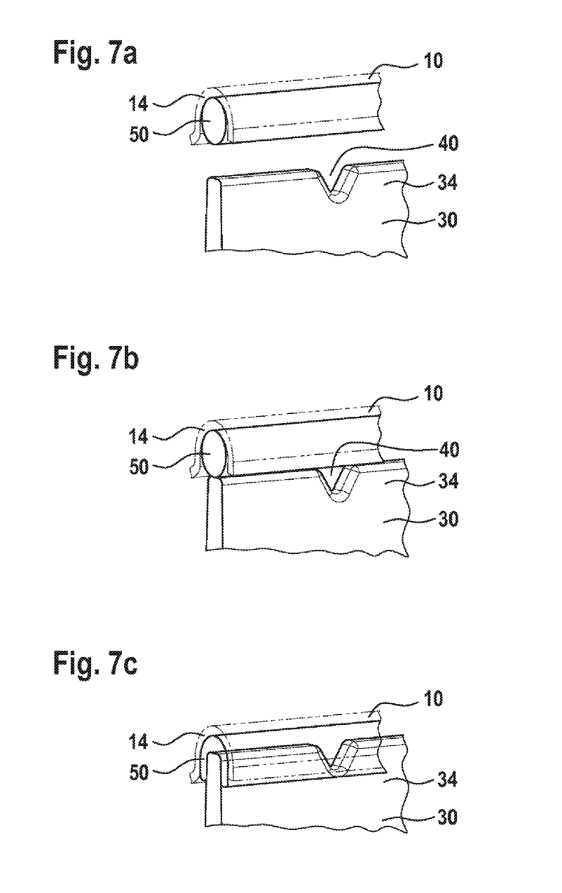

Illustrated in FIGS. 7a, 7b and 7c are the individual stages for the assembly of a housing 1 according to the invention with a recess which forms a channel 40. The recess which forms the channel 40 is formed for example as a triangular notch. FIG. 7a shows a section of the first housing element 10 and of the second housing element 30 prior to the assembly or prior to the bringing-together of the first housing element 10 and the second housing element 30. The first housing element 10 has a groove 14. The connecting means 50 extends inside the groove 14. The connecting means 50 is in particular of cylindrical form and has a circular cross section. A rectangular or oval cross section is also possible, however. Corresponding to said formation, the groove 14 is of substantially C-shaped form in cross section. In particular, the diameter of the connecting element 50 corresponds to the inner diameter of the groove 14. The channel 40 is formed as a recess, in particular as a notch, in the tongue 34 of the second housing element 30.

According to a refinement of the invention, the formation of any desired number of channels 40, in particular in the form of recesses or apertures, preferably notches and/or holes on one and/or both of the housing elements 10, 30, is possible.

In FIG. 7b, the same section of the first housing element 10 and of the second housing element 30 according to FIG. 7a is illustrated during the assembly. The first housing element 10 and the second housing element 30 have already been brought together to such an extent that contact of the connecting element 50 with the second housing element 30 occurs. In spite of the contact of the connecting element 50 with the first housing element 10 and the second housing element 30, a fluid flow out of the inner region 5 of the housing 1 is possible by way of at least one channel 40, the latter being formed in particular by a recess and preferably by a notch. Such a fluid flow forms as a result of the displacement of the fluid inside the housing 1 during the assembly, in particular during the bringing-together of the housing elements 10, 30 during the assembly.

FIG. 7c illustrates the same section as in FIGS. 7a and 7b after the assembly, or after the bringing-together of the housing elements 10, 30. The connecting element 50 has, as desired, been displaced, in particular in a uniform manner. Blowing-out of the sealing means, as shown by way of example in FIG. 5, in particular due to the fluid flowing out of the housing 1 during the assembly, has been prevented. Also, the formation of partially occurring, unsealed points past which, in particular, the fluid is caused to flow when leaving the inner region 5 during the bringing-together procedure, has been prevented. The connecting element 50 has a C-shaped form and closes off the recess 40, which formed a channel 40 during the assembly, preferably from both sides of the tongue 34. The housing 1 is thus sealed off after the assembly such that no entry of fluids, in particular liquids, into the inner region of the housing 1 between the housing elements 10, 30 is possible.

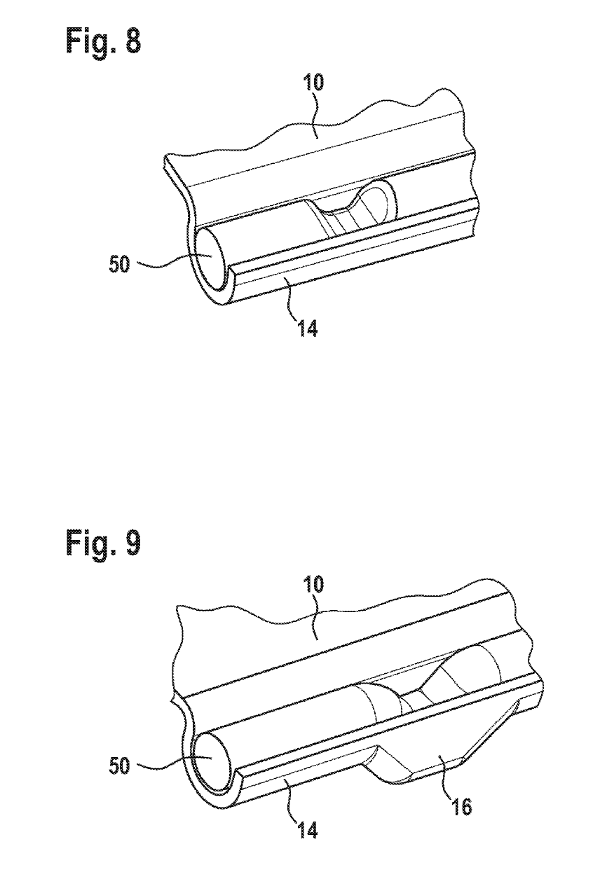

FIG. 8 shows a further embodiment according to the invention. In this embodiment too, the connection of the first housing element 10 to the second housing element 30 occurs via a tongue-and-groove connection. Consequently, here too, the first housing element 10 has a groove 14 and the second housing element has a tongue 34. For the sake of simplicity, only a section of the groove 14 of the first housing element 10 is illustrated in FIG. 8. The connecting element 50 is arranged inside the groove 14, which has a C-shaped cross section. The connecting element 50 is of cylindrical form in cross section. At at least one point, it has a recess, in particular it has a smaller cross section, preferably a partially reduced height. The recess or the smaller cross section allow the formation of a channel 40 according to the invention during the assembly. Any desired number of such recesses with a smaller cross section may be formed at the connecting element.

FIG. 9 shows a further embodiment according to the invention. In this embodiment too, the connection of the first housing element 10 to the second housing element 30 occurs via a tongue-and-groove connection. Consequently, here too, the first housing element 10 has a groove 14 and the second housing element has a tongue 34. For the sake of simplicity, only a section of the groove 14 of the first housing element 10 is illustrated in FIG. 9. The groove 14 has, in part, a protuberance 16. The protuberance 16 is formed on that side of the housing element 10 which faces away from the tongue. The connecting element 50 is guided inside the protuberance 16. As a result of the protuberance 16, the connecting element 50 is arranged at a distance from the tongue 34 in the region of the protuberance prior to and during the assembly. In spite of partial contact of the connecting element 50 with the tongue 34 in other regions, no contact of the connecting element 50 and the tongue 34 occurs in the region of the partial formation of the protuberance 16 in the groove 14 prior to and/or during the bringing-together, in particular the assembly of the housing 1. Consequently, a channel 40 according to the invention is formed, which allows pressure equalization or fluid flow during assembly.

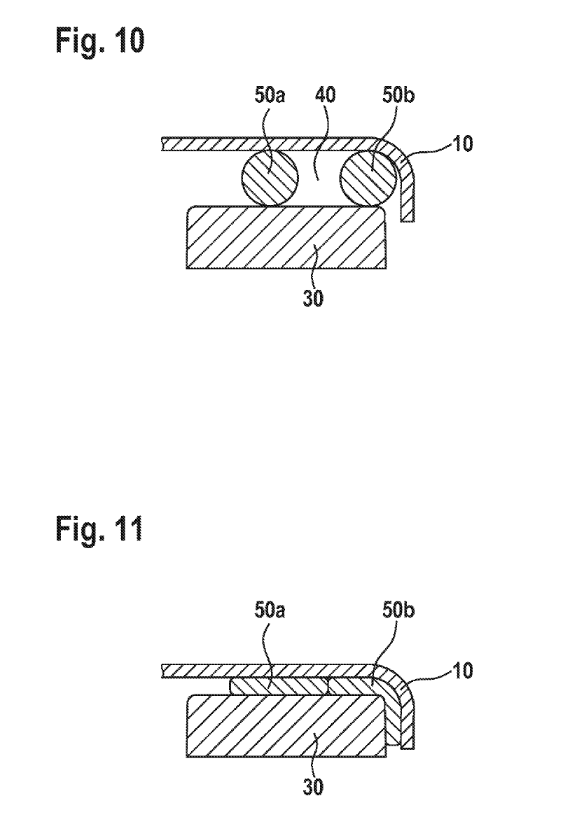

FIGS. 10, 11 and 12 show a further embodiment according to the invention. In the further embodiment, the housing elements 10, 30 are formed such that two connecting elements 50a, 50b are able to be arranged. Furthermore, the first housing element 10 has an edge region which is substantially bent at right angles. The edge region in particular prevents displacement of the housing elements 10, 30. The channel 40 according to the invention forms as a gap between the two connecting elements 50a, 50b during the assembly. The channel 40 is illustrated by way of example in FIG. 10 between the two connecting elements 50a, 50b. The channel 40 is closed off as a result of the bringing-together of the housing elements 10, 30 during the assembly of the housing 1. The closure occurs in particular as a result of the displacement of the connecting elements 50a and 50b. The two connecting elements 50a and 50b make contact with one another and close off the channel 40.

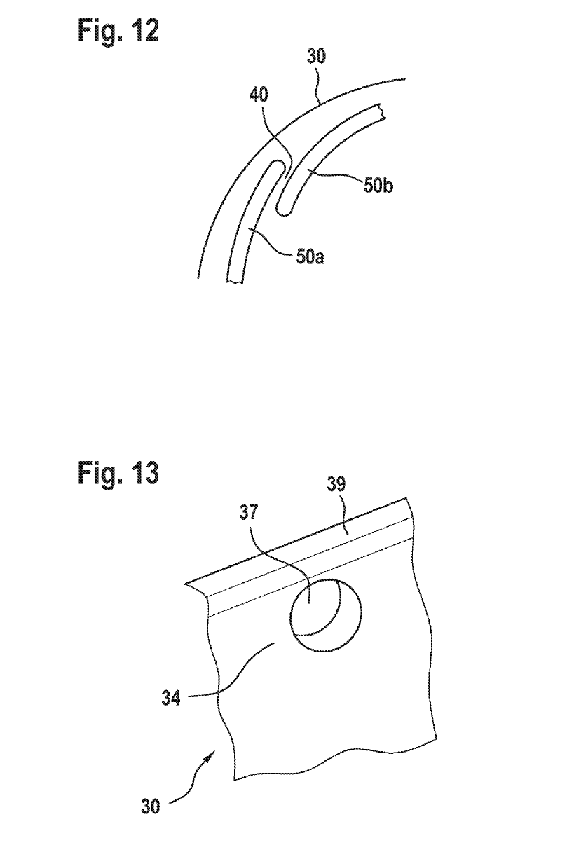

According to FIG. 12, the connecting elements 50a, 50b are arranged partly parallel to one another. The channel 40 extends between the two connecting elements 50a and 50b until the completion of the assembly. The channel 40 is formed in the region of the connecting elements 50a, 50b arranged parallel to one another. The connecting elements 50 are compressed as a result of the bringing-together of the housing elements 10, 30. The compression leads to a widening of the connecting elements 50. As a result of the widening of the connecting elements 50, the channel 40 is closed off in a fluid-tight manner.

FIG. 13 shows a further embodiment of the invention. According to the further embodiment of the invention, the channel 40 is formed by way of an aperture 37, in particular a depression, preferably a bore 37. The bore 37 is formed in particular beneath the edge region 39 of the tongue 34, which region faces toward the groove. The aperture, in particular the bore 37, is arranged at the tongue 34 such that closure of the bore, and thus the channel 40, by the connecting element 50 occurs after completion of the assembly.

The tongue-and-groove connection is formed so as to partially, in particularly completely, extend circumferentially around the housing elements 10, 30. In particular, the tongue-and-groove connection is formed in the edge region of the housing elements 10, 30. Advantageously, the tongue-and-groove connection is also formed in the region of the electrical connection plug 64. The term “completely” also includes in this case a tongue-and-groove connection with one and multiple partial interruptions of the tongue-and-groove connection, wherein the interruptions are in particular less than 10% of the total circumference of the housing.

1. A housing (1), with at least two housing elements (10, 30) and a connecting element (50), wherein the housing elements (10, 30) interact with the connecting element (50), and wherein the housing elements (10, 30) when assembled form an inner region (5), characterized in that a channel (40) is formed, which connects the inner region (5) and surroundings of the housing (1), and permits fluid flow between the inner region (5) and the surroundings, prior to and/or during assembly of the housing (1), and which is closed off by way of interaction of at least one housing element (10, 30) and the connecting element (50) upon completion of the assembly.

2. The housing (1) as claimed in claim 1, characterized in that the channel (40) is closed off, by the connecting element (50) upon completion of the assembly.

3. The housing (1) as claimed in claim 1, characterized in that the connecting element (50) connects the housing elements (10, 30) in a sealed manner, upon completion of the assembly of the housing (1).

4. The housing (1) as claimed in claim 1, characterized in that the channel (40) is formed by way of a recess, a narrowing or an aperture in one of the housing elements (10, 30).

5. The housing (1) as claimed in claim 1, characterized in that the housing elements (10, 30) interact by means of a tongue-and-groove connection (14, 34), wherein the second housing element (30) has a tongue (34) and the first housing element (10) has a corresponding groove (14), and wherein the tongue (34) engages into the groove (14).

6. The housing (1) as claimed in claim 5, characterized in that the groove (14) of the first housing element (10) and the tongue (34) of the second housing element (30) are formed so as to at least partially extend circumferentially around the housing elements (10, 30).

7. The housing (1) as claimed in claim 5, characterized in that the channel (40) is formed by way of a recess, an aperture in the tongue (34) or a narrowing of the tongue (34) of the second housing element (30).

8. The housing (1) as claimed in claim 5, characterized in that the groove (14) at least partially guides the connecting element (50).

9. The housing (1) as claimed in claim 5, characterized in that the groove (14) has a partial protuberance (16), wherein, as a result of the partial protuberance (16), the connecting element (50) forms a channel (40) in the region of the partial protuberance (16) prior to and/or during the assembly.

10. The housing (1) as claimed in claim 1, characterized in that the connecting element (50) is formed as a wet seal.

11. The housing (1) as claimed in claim 1, characterized in that the connecting element (50) is of cylindrical form.

12. The housing (1) as claimed in claim 1, characterized in that the channel (40) is formed by way of a partially reduced cross section of the connecting element (50).

13. The housing (1) as claimed in claim 1, characterized in that two connecting elements (50a, 50b) are formed, wherein the channel (40) is formed between the two connecting elements (50a, 50b) prior to and during the assembly, and the connecting elements (50a, 50b) close off the channel (40) upon completion of the assembly.

14. The housing (1) as claimed in claim 1, characterized in that two or more channels (40) are formed prior to and/or during the assembly of the housing (1), wherein the channels (40) are closed off upon completion of the assembly.

15. The housing (1) as claimed in claim 1, wherein the housing is for a control unit of a fan motor, and wherein the channel (40) permits fluid flow between the inner region (5) and the surroundings prior to and/or during assembly of the housing elements (10, 30).

16. The housing (1) as claimed in claim 1, characterized in that the channel (40) is closed off in a sealed manner by the connecting element (50) upon completion of the assembly.

17. The housing (1) as claimed in claim 1, characterized in that the connecting element (50) connects the housing elements (10, 30) in such a way that no fluid flow can develop between the housing elements (10, 30) upon completion of the assembly of the housing (1).

18. The housing (1) as claimed in claim 5, characterized in that the channel (40) is formed by way of a recess, an aperture in the tongue (34) or a narrowing of the tongue (34) of the second housing element (30), wherein the channel (40) is formed by way of a triangular, semicircular or square notch formed in the tongue (34).

19. The housing (1) as claimed in claim 5, characterized in that the connecting element (50) extends inside the groove (14).

20. The housing (1) as claimed in claim 1, characterized in that the channel (40) is formed by way a narrowing of the connecting element (50).

21. The housing (1) as claimed in claim 1, characterized in that two connecting elements (50a, 50b) are formed, wherein the channel (40) is formed between the two connecting elements (50a, 50b) prior to and during the assembly, and the connecting elements (50a, 50b) close off the channel (40) and make contact with one another, upon completion of the assembly.

22. The housing (1) as claimed in claim 1, characterized in that two or more channels (40) are formed prior to and/or during the bringing-together of the housing elements (10, 30), wherein the channels (40) are closed off upon completion of the assembly.
